(19) United States
(12) Patent Application Publication
(10) Pub. No.: US 2025/0151578 A1
(43) Pub. Date: May 8, 2025

(54) DISPLAY MODULE AND DISPLAY TERMINAL

(71) Applicant: WUHAN CHINA STAR OPTOELECTRONICS SEMICONDUCTOR DISPLAY TECHNOLOGY CO., LTD., Wuhan (CN)

(72) Inventors: Yanqiang DUAN, Wuhan (CN); Ju FANG, Wuhan (CN)

(21) Appl. No.: 18/564,187

(22) PCT Filed: Nov. 10, 2023
(86) PCT No.: PCT/CN2023/131032

§ 371 Date: Nov. 27, 2023

(30) Foreign Application Priority Data
Nov. 3, 2023 (CN) 202311465904.7

(51) Int. Cl. H10K 59/80; H10K 59/126; H10K 102/00

(52) U.S. Cl. CPC H10K 59/873; H10K 59/126; H10K 2102/311

(57) ABSTRACT

An embodiment of the present application discloses a display module and a display terminal, and the display module and the display terminal include a display panel and a cover plate. The cover plate has an attaching curved surface facing the display panel, a portion of the attaching curved surface is attached with a display side of the display panel through a transparent glue, and the attaching curved surface fully covers a display main body and a bending portion. The bending portion includes a wiring and at least one groove, and the groove extends along a bending direction of the bending portion and is positioned outside the wiring.

### TECHNICAL FIELD

The present application relates to the field of display technologies, and more particularly, to a display module and a display terminal.

### BACKGROUND

With a display module, on one hand, a binding portion of a display panel needs to be bent to back of the display panel through a bending portion, and the bending portion is affected by bending stress in vertical bending direction. On the other hand, as the full-curved cover plate is assembled to the display panel, the bending portion of the display panel is affected by shape of the full-curved cover plate to bend along bending direction of the full-curved cover plate. The bending portion is further affected by the bending stress in the bending direction of the full-curved cover plate. Bending central axes of the bending stresses in above directions are perpendicular to each other, so that an arc top (at elliptical circle) of the bending portion is inclined toward CG side of the cover plate (as shown in FIG. 1). However, because a region of the full-curved cover plate with a small radius curvature corresponds to the bending portion, the bending radius at the arc top becomes locally less and the stress becomes greater, thereby causing breakage of wirings at the arc top.

### SUMMARY

An embodiment of the present application provides a display module and a display terminal, which can reduce a risk of breakage of a wiring in a bending portion of a display panel.

An embodiment of the present application provides a display module including:
a display panel, where the display panel includes a display main body, a bending portion, and a binding portion sequentially connected to each other, and the binding portion is provided on a back of the display main body through the bending portion; and
a cover plate, where the cover plate has an attaching curved surface facing the display panel, a portion of the attaching curved surface is attached to a display side of the display panel by a transparent glue, and the attaching curved surface fully covers the display main body and the bending portion;
where the bending portion includes a wiring and at least one groove, and the groove extends along a bending direction of the bending portion and is disposed outside the wiring.

In some embodiments of the present application, in a longitudinal axis direction of the bending portion, the attaching curved surface has a consistent curvature radius, and a plurality of the grooves are uniformly disposed.

In some embodiments of the present application, in a longitudinal axis direction of the bending portion, the bending portion includes a first region and a second region, and the second region is disposed on an opposite side of the first region;
where the attaching curved surface includes a first curved surface covering the first region and a second curved surface covering the second region, the second curved surface is connected to the first curved surface at opposite sides, and in the longitudinal axis direction of the bending portion, a curvature radius of the first curved surface is consistent, a curvature radius of the second curved surface is consistent, and the curvature radius of the first curved surface is greater than the curvature radius of the second curved surface;
where a number of the grooves in the first region is smaller than a number of the grooves in the second region at same arc length.

In some embodiments of the present application, a distance between two adjacent grooves of the first region is greater than a distance between two adjacent grooves of the second region.

In some embodiments of the present application, in a longitudinal axis direction of the bending portion, the bending portion includes a first region and a second region, and the second region is disposed on an opposite side of the first region;
where the attaching curved surface includes a first curved surface covering the first region and a second curved surface covering the second region, the second curved surface is connected to the first curved surface at opposite sides, and in the longitudinal axis direction of the bending portion, a curvature radius of the first curved surface is consistent, and a curvature radius of the second curved surface decreases in a direction from a side of the second curved surface connected to the first curved surface toward a side of the second curved surface away from the first curved surface;
where a number of the grooves in the first region is smaller than a number of the grooves in the second region at same arc length.

In some embodiments of the present application, a density of the grooves in the second region increases in a direction from a side of the second region connected to the first region toward a side of the second region away from the first region.

In some embodiments of the present application, the display panel includes:
a flexible substrate provided corresponding to the display body, the bending portion, and the binding portion;
a thin film transistor structure layer, where the thin film transistor structure layer includes a thin film transistor and an inorganic insulating stacked layer, the thin film transistor is provided corresponding to the display main body, the inorganic insulating stacked layer is disposed at least corresponding to the display main body and the binding portion, the inorganic insulating stacked layer being provided with an opening, and the opening is disposed corresponding to the bending portion; and
an organic layer disposed on the thin film transistor structure layer, where the organic layer is extended from the display body to cover the bending portion and filled in the opening, and the wiring is disposed on the organic layer;
where in the bending portion, the organic layer is provided with the groove, and the groove is extended through at least a portion of the organic layer.

In some embodiments of the present application, the thin film transistor structure layer includes a light-shielding layer, a buffer layer, a first active layer, a first insulating layer, a first metal layer, a second insulating layer, a second metal layer, a first interlayer dielectric layer, a second active layer, a third insulating layer, a third metal layer, a second interlayer dielectric layer, and a fourth metal layer;
where the light-shielding layer is disposed on the flexible substrate; the buffer layer is disposed on the light-shielding layer and covers the flexible substrate; the first active layer is disposed on the buffer layer; the first insulating layer covers the first active layer and the buffer layer; the first metal layer is disposed on the first insulating layer; the first metal layer includes a first gate electrode overlapped with the first active layer; the second insulating layer covers the first metal layer and the first insulating layer; the second metal layer is disposed on the second insulating layer; the second metal layer includes an electrode plate and a second gate electrode; the electrode plate is overlapped with the first gate electrode to define a capacitance; the second gate electrode is disposed on a side of the electrode plate; the first interlayer dielectric layer covers the second metal layer and the second insulating layer; the second active layer is disposed on the first interlayer dielectric layer; the second active layer is overlapped with the second gate electrode; the third insulating layer covers the second active layer and the first interlayer dielectric layer; the third metal layer is disposed on the third insulating layer; the third metal layer includes a third gate electrode overlapped with the second active layer; the second interlayer dielectric layer covers the third metal layer and the third insulating layer; the fourth metal layer is disposed on the second interlayer dielectric layer; the fourth metal layer includes a first source electrode, a first drain electrode, a second source electrode and a second drain electrode; the first source electrode and the first drain electrode are connected to the first active layer; and the second source electrode and the second drain electrode are connected to the second active layer;
where the buffer layer, the first insulating layer, the second insulating layer, the first interlayer dielectric layer, the third insulating layer, and the second interlayer dielectric layer are stacked to define the inorganic insulating stacked layer, and the opening is extended through at least one layer of the inorganic insulating stacked layer.

n some embodiments of the present application, the display panel further includes a protective layer covering the bending portion, the protective layer is extended to cover a portion of the display main body and a portion of the binding portion, and the groove is extended through the protective layer;
where the display panel includes an encapsulating glue filled in the groove.

In some embodiments of the present application, the display panel includes:
a flexible substrate provided corresponding to the display body, the bending portion, and the binding portion; and
a thin film transistor structure layer, where the thin film transistor structure layer includes a thin film transistor and an inorganic insulating stacked layer; the thin film transistor is provided corresponding to the display main body; the inorganic insulating stacked layer is disposed corresponding to the display main body, the bending portion, and the binding portion; the inorganic insulating stacked layer is provided with a plurality of openings corresponding to the bending portion; the plurality of opening is arranged in a longitudinal axis direction of the bending portion, and is extended in a bending direction of the bending portion; and at least one of a source electrode, a drain electrode, and a gate electrode of the thin film transistor is disposed in a same layer with the wiring;
where each of the plurality of openings is filled with an organic material, the groove is defined on the organic material, and a depth of the groove is less than a thickness of the organic material, or the groove penetrates through all film layers of the bending portion.

Accordingly, the embodiment of the present application further provides a display terminal including the display module according to any one of the above embodiments.

For example, the display module includes:
a display panel, where the display panel includes a display main body, a bending portion, and a binding portion sequentially connected to each other, and the binding portion is provided on a back of the display main body through the bending portion; and
a cover plate, where the cover plate has an attaching curved surface facing the display panel, a portion of the attaching curved surface is attached to a display side of the display panel by a transparent glue, and the attaching curved surface fully covers the display main body and the bending portion;
where the bending portion includes a wiring and at least one groove, and the groove extends along a bending direction of the bending portion and is disposed outside the wiring.

In some embodiments of the present application, in a longitudinal axis direction of the bending portion, the attaching curved surface has a consistent curvature radius, and a plurality of the grooves are uniformly disposed.

In some embodiments of the present application, in a longitudinal axis direction of the bending portion, the bending portion includes a first region and a second region, and the second region is disposed on an opposite side of the first region;
where the attaching curved surface includes a first curved surface covering the first region and a second curved surface covering the second region, the second curved surface is connected to the first curved surface at opposite sides, and in the longitudinal axis direction of the bending portion, a curvature radius of the first curved surface is consistent, a curvature radius of the second curved surface is consistent, and the curvature radius of the first curved surface is greater than the curvature radius of the second curved surface;
where a number of the grooves in the first region is smaller than a number of the grooves in the second region at same arc length.

In some embodiments of the present application, a distance between two adjacent grooves of the first region is greater than a distance between two adjacent grooves of the second region.

In some embodiments of the present application, in a longitudinal axis direction of the bending portion, the bending portion includes a first region and a second region, and the second region is disposed on an opposite side of the first region;
where the attaching curved surface includes a first curved surface covering the first region and a second curved surface covering the second region, the second curved surface is connected to the first curved surface at opposite sides, and in the longitudinal axis direction of the bending portion, a curvature radius of the first curved surface is consistent, and a curvature radius of the second curved surface decreases in a direction from a side of the second curved surface connected to the first curved surface toward a side of the second curved surface away from the first curved surface;
where a number of the grooves in the first region is smaller than a number of the grooves in the second region at same arc length.

In some embodiments of the present application, a density of the grooves in the second region increases in a direction from a side of the second region connected to the first region toward a side of the second region away from the first region.

In some embodiments of the present application, the display panel includes:
a flexible substrate provided corresponding to the display body, the bending portion, and the binding portion;
a thin film transistor structure layer, where the thin film transistor structure layer includes a thin film transistor and an inorganic insulating stacked layer, the thin film transistor is provided corresponding to the display main body, the inorganic insulating stacked layer is disposed at least corresponding to the display main body and the binding portion, the inorganic insulating stacked layer being provided with an opening, and the opening is disposed corresponding to the bending portion; and
an organic layer disposed on the thin film transistor structure layer, where the organic layer is extended from the display body to cover the bending portion and filled in the opening, and the wiring is disposed on the organic layer;
where in the bending portion, the organic layer is provided with the groove, and the groove is extended through at least a portion of the organic layer.

In some embodiments of the present application, the thin film transistor structure layer includes a light-shielding layer, a buffer layer, a first active layer, a first insulating layer, a first metal layer, a second insulating layer, a second metal layer, a first interlayer dielectric layer, a second active layer, a third insulating layer, a third metal layer, a second interlayer dielectric layer, and a fourth metal layer;
where the light-shielding layer is disposed on the flexible substrate; the buffer layer is disposed on the light-shielding layer and covers the flexible substrate; the first active layer is disposed on the buffer layer; the first insulating layer covers the first active layer and the buffer layer; the first metal layer is disposed on the first insulating layer; the first metal layer includes a first gate electrode overlapped with the first active layer; the second insulating layer covers the first metal layer and the first insulating layer; the second metal layer is disposed on the second insulating layer; the second metal layer includes an electrode plate and a second gate electrode; the electrode plate is overlapped with the first gate electrode to define a capacitance; the second gate electrode is disposed on a side of the electrode plate; the first interlayer dielectric layer covers the second metal layer and the second insulating layer; the second active layer is disposed on the first interlayer dielectric layer; the second active layer is overlapped with the second gate electrode; the third insulating layer covers the second active layer and the first interlayer dielectric layer; the third metal layer is disposed on the third insulating layer; the third metal layer includes a third gate electrode overlapped with the second active layer; the second interlayer dielectric layer covers the third metal layer and the third insulating layer; the fourth metal layer is disposed on the second interlayer dielectric layer; the fourth metal layer includes a first source electrode, a first drain electrode, a second source electrode and a second drain electrode; the first source electrode and the first drain electrode are connected to the first active layer; and the second source electrode and the second drain electrode are connected to the second active layer;
where the buffer layer, the first insulating layer, the second insulating layer, the first interlayer dielectric layer, the third insulating layer, and the second interlayer dielectric layer are stacked to define the inorganic insulating stacked layer, and the opening is extended through at least one layer of the inorganic insulating stacked layer.

### Beneficial Effect

A display module according to an embodiment of the present application includes a display panel and a cover plate. The display panel includes a display main body, a bending portion, and a binding portion connected sequentially, and the binding portion is provided on a back of the display main body through the bending portion. The cover plate has an attaching curved surface facing the display panel, a portion of the attaching curved surface is adhered to a display side of the display panel through transparent glue, and the attaching curved surface covers the display main body and the bending portion completely. The bending portion includes a wiring, and at least one groove is defined in the bending portion. The groove extends along a bending direction of the bending portion and is positioned outside the wiring.

The display module according to the embodiment of the present application is provided with the groove on the bending portion to release bending stress on the bending portion, thereby reducing a risk of breakage of the wiring in the bending portion.

### BRIEF DESCRIPTION OF THE DRAWINGS

FIG. 1 is a schematic diagram of a display module provided in related art.

FIG. 2 is a schematic bottom diagram of a display module according to Embodiment 1 of the present application.

FIG. 3 is a schematic cross-sectional diagram taken along line BB in FIG. 2.

FIG. 4 is an enlarged view of part C1 in FIG. 3.

FIG. 5 is a schematic cross-sectional diagram taken along line CC in FIG. 2.

FIG. 6 is an enlarged view of part C2 in FIG. 5.

FIG. 7 is a schematic top diagram of a display panel of a display module according to Embodiment 1 of the present application in an expanded state.

FIG. 8 is a schematic sectional diagram of a display panel of a display module according to Embodiment 1 of the present application in an expanded state.

FIG. 9 is a schematic bottom diagram of a display module according to Embodiment 2 of the present application.

FIG. 10 is a schematic cross-sectional diagram taken along line CC in FIG. 9.

FIG. 11 is a schematic top diagram of a display panel of a display module according to Embodiment 2 of the present application in an expanded state.

FIG. 12 is a simulation experiment diagram of Comparative Example 1 and Comparative Example 2.

FIG. 13 is a schematic bottom diagram of a display module according to Embodiment 3 of the present application.

FIG. 14 is a schematic cross-sectional diagram taken along line CC in FIG. 13.

FIG. 15 is a schematic top diagram of a display panel of a display module according to Embodiment 3 of the present application in an expanded state.

FIG. 16 is a schematic cross-sectional diagram of a display panel of a display module according to Embodiment 4 of the present application in an expanded state.

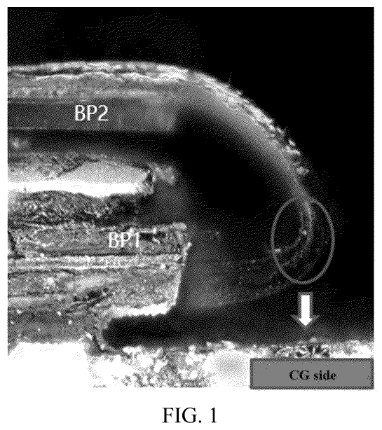

In FIG. 1, BP1 and BP2 are backplanes supporting a display panel.

### DETAILED DESCRIPTION OF THE EMBODIMENTS

In the following, the technical solutions in the embodiments of the present application will be clearly and completely described in connection with the accompanying drawings in the embodiments of the present application. It should be understood that the described embodiments are merely a part of embodiments implemented by the present application, rather than all embodiments. Based on the embodiments in the present application, all other embodiments obtained by a person skilled in the art without involving any inventive effort are in the scope of the present application. Furthermore, it should be understood that the embodiments described herein are for purposes of illustration and explanation only and are not intended to limit the application. In the present application, if not stated to the contrary, the use of positional terms such as “on” and “under” refers to a position on or under a device in actual use or working state, and the terms “in” and “out” are for the outline of the device. The terms “first”, “second”, “third”, and the like are used merely as labels and do not impose numerical requirements or establish orders.

An embodiment of the present application provides a display module and a display terminal, which are described in detail below. It should be noted that the order in which the following examples are described is not intended to limit the preferred order of the examples.

A display module and a display terminal according to an embodiment of the present application each include a display panel and a cover plate, where the display panel includes a display main body, a bending portion, and a binding portion. The binding portion is provided on a back of the display main body through the bending portion. The cover plate has an attaching curved surface facing the display panel, a portion of the attaching curved surface is adhered to a display side of the display panel through transparent glue, and the attaching curved surface covers the display main body and the bending portion completely. The bending portion includes a wiring, and at least one groove is defined in the bending portion. The groove extends along a bending direction of the bending portion and is positioned outside the wiring.

The display module according to the embodiment of the present application is provided with the groove on the bending portion to release bending stress on the bending portion, thereby reducing a risk of wiring breakage of the bending portion.

It should be understood that the bending portion is subjected to bending stresses from two bending directions, where a first bending direction is a bending direction in which the bending portion itself is bent toward the back of the display body; and a second bending direction is a bending direction in which the bending portion is bent through being affected by a shape of the adhering surface of the cover plate as the display panel is attached to the upper cover plate. The arrangement of the grooves can release the bending stresses in both bending directions at the same time, which is better for release and relief of the stress in the second bending direction.

According to this application, grooves are provided in different densities correspondingly to the shapes of the adhering curved surface of the cover plate with different curvature radius, so that the bending stress of the bending portion is sufficiently released and relieved.

### Embodiment 1

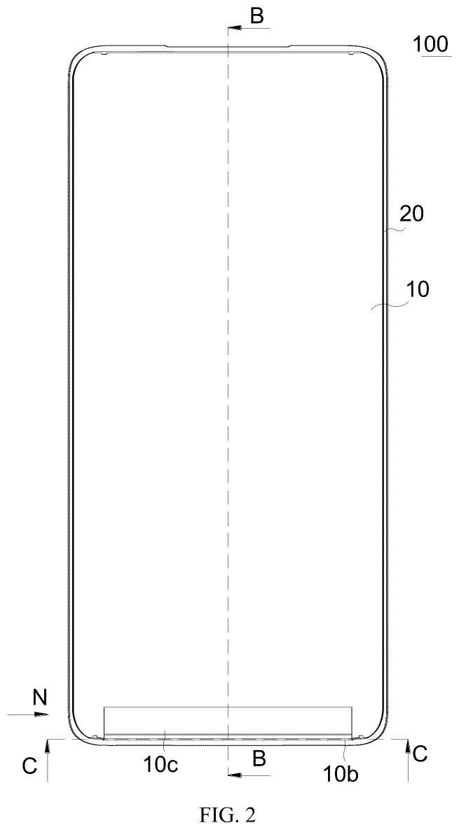

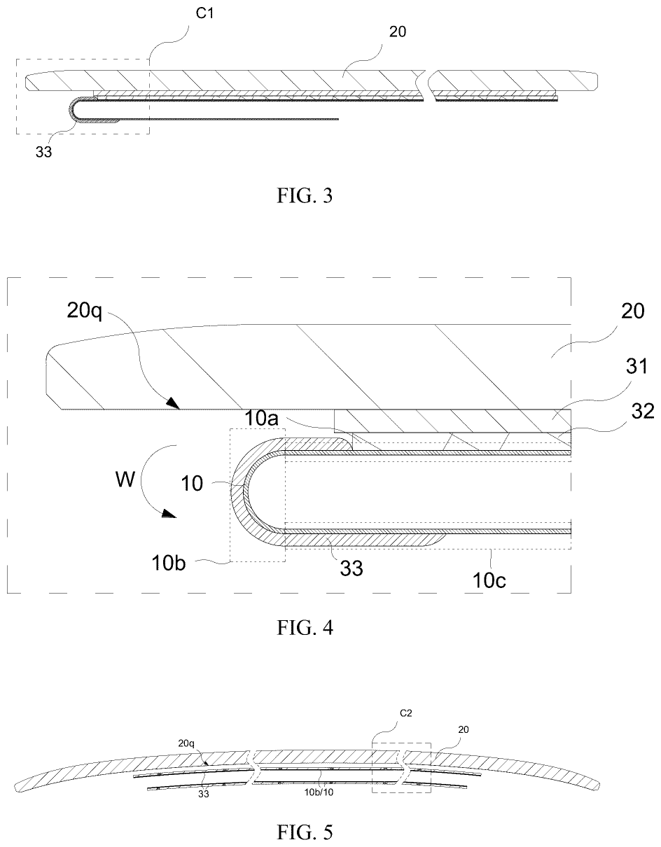

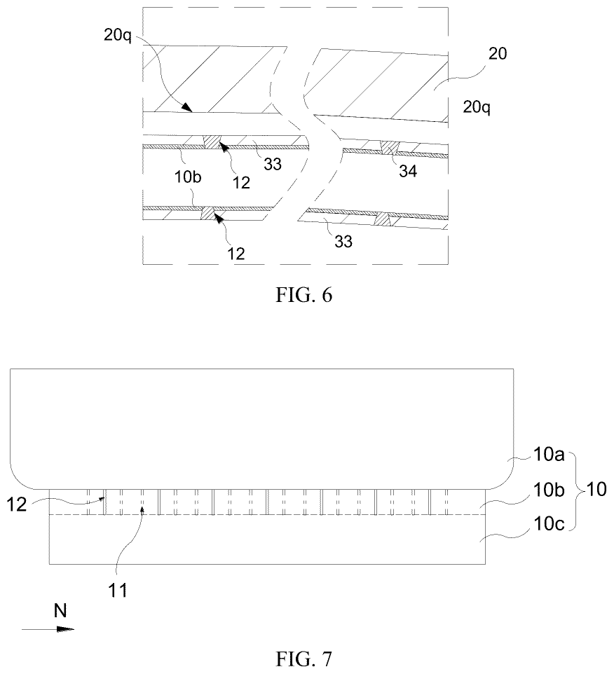

Referring to FIGS. 2 to 6, an embodiment of the present application provides a display module 100 including a display panel 10 and a cover plate 20.

The display panel 10 includes a display main body 10a, a bending portion 10b, and a binding portion 10c connected in sequence, and the binding portion 10c is provided on a back surface of the display main body 10a through the bending portion 10b. The cover plate 20 is attached to a display side of the display panel 10 by a transparent glue 31.

In an embodiment, in a stacked structure of film layers, the display module 100 may further include a polarizer 32 and a protective layer 33.

The polarizer 32 is provided on the display main body 10a, and the transparent glue 31 is provided on the polarizer 32.

The protective layer 33 covers the bending portion 10b, and extends to cover a portion of the display main body 10a and a portion of the binding portion 10c.

In an embodiment, a groove 12 extends through the protective layer 33. The material of the protective layer 33 may be a glue, such as a UV-curable glue.

In an embodiment, the display panel 10 is one of an organic light-emitting display panel (OLED), a quantum dot light-emitting display panel (QLED), or a miniature inorganic light-emitting display panel (u-LED).

In an embodiment, the polarizer 32 may also be replaced with a color film layer integrated in the display panel 10.

In an embodiment, the cover plate 20 has an attaching curved surface 20q facing the display panel 10. A portion of the adhering surface 20q is attached to a display side of the display panel 10 by the transparent glue 31. The adhering surface 20q covers the display main body 10a and the bending portion 10b completely.

The bending portion 10b includes a wiring 11. At least one groove 12 is defined in the bending portion 10b. The groove 12 extends along a bending direction W of the bending portion 10b and is disposed on the outside of the wiring 11.

The display module 100 according to the embodiment of the present application is provided with the groove 12 on the bending portion 10b to release the bending stress on the bending portion 10b, thereby reducing a risk of breaking the wiring 11 of the bending portion 10b.

Referring to FIG. 7, in an embodiment, in a longitudinal axis direction N of the bending portion 10b, the attaching curved surface 20q has a consistent curvature radius, and the plurality of grooves 12 are uniformly disposed.

Since the attaching curved surface 20q has a consistent curvature radius, the cover plate 20 applies a relatively uniform bending stress to the bending portion 10b.

The grooves 12 provided on the bending portion 10b sufficiently release and relieve the bending stress of the bending portion 10b.

The grooves 12 are formed in same process as cutting the contour of the display panel 10.

The longitudinal axis direction N of the bending portion 10b is parallel to a minor edge of the display module 100.

In an embodiment, the attaching curved surface 20q of the cover plate 20 extends beyond the display panel 10.

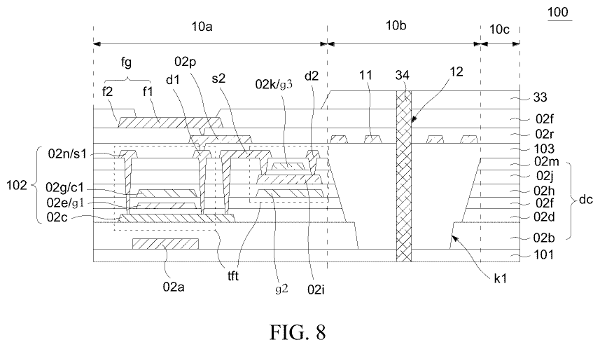

Referring to FIG. 8, in an embodiment, the display panel 10 includes a flexible substrate 101, a thin film transistor structure layer 102, and an organic layer 103.

The flexible substrate 101 is provided in regions corresponding to the display main body 10a, the bending portion 10b, and the binding portion 10c.

The thin film transistor structure layer 102 includes a thin film transistor tft in a region corresponding to the display main body 10a, and an inorganic insulating stacked layer dc. The inorganic insulating stacked layer dc is provided at least in corresponding to the display main body 10a and the binding portion 10c. The inorganic insulating stacked layer dc is provided with an opening k1. The opening k1 is provided corresponding to the bending portion 10b.

An organic layer 103 is provided on the thin film transistor structure layer 102. The organic layer 103 extends from the region corresponding to the display main body 10a to cover the region corresponding to the bending portion 10b to fill the opening k1. The wiring 11 is provided on the organic layer 103.

In the region corresponding to the bending portion 10b, the groove 12 is defined in the organic layer 103 and extends through at least a portion of the organic layer 103.

According to the embodiment of the present application, the inorganic insulating stacked layer dc corresponding to the bending portion 10b is removed, and the opening k1 is filled with the organic layer 103. Since the organic layer 103 has a stronger stress absorption ability than the inorganic insulating stacked layer dc, the above-described arrangement can improve the bending performance of the bending portion 10b and further reduce the risk of breaking the wiring 11. Further, the organic layer 103 is more flexible than the inorganic insulating stacked layer dc, and with the groove 12 defined by the laser, the organic layer 103 can reduce the risk of peeling under the action of the bending portion 10b in two bending directions.

In an embodiment, the groove 12 further extends through the flexible substrate 101. That is, the groove 12 extend through all film layers of the bending portion 10b of the display panel 10, to improve the stress release performance of the bending portion 10b.

In an embodiment, the display panel 10 further includes a light-emitting device fg disposed on the thin film transistor structure layer 102 and electrically connected to the thin film transistor tft.

It should be noted that the thin film transistor tft of the thin film transistor structure layer 102 may be at least one of a top gate type, a bottom gate type, and a double gate type. The thin film transistor structure layer 102 may be a thin film structure of a single thin film transistor tft, or may be a stacked structure of at least two thin film transistors tft. The embodiment of the present application is described by taking one of the stacked structure of the two thin film transistors tft as an example, but is not limited thereto.

In an embodiment, the thin film transistor structure layer 102 includes a light-shielding layer 02a, a buffer layer 02b, a first active layer 02c, a first insulating layer 02d, a first metal layer 02e, a second insulating layer 02f, a second metal layer 02g, a first interlayer dielectric layer 02h, a second active layer 02i, a third insulating layer 02j, a third metal layer 02k, a second interlayer dielectric layer 02m, and a fourth metal layer 02n.

A light-shielding layer 02a is provided on the flexible substrate 101. A buffer layer 02b is provided on the light-shielding layer 02a and covers the flexible substrate 101. A first active layer 02c is provided on the buffer layer 02b. A first insulating layer 02d covers the first active layer 02c and the buffer layer 02b. A first metal layer 02e is provided on the first insulating layer 02d. The first metal layer 02e includes a first gate electrode g1 overlapped with the first active layer 02c. The second insulating layer 02f covers the first metal layer 02e and the first insulating layer 02d. The second metal layer 02g is provided on the second insulating layer 02f. The second metal layer 02g includes an electrode plate cl and a second gate g2. The electrode plate cl and the first gate g1 are overlapped to define a capacitance. The second gate electrode g2 is located on a side of the electrode plate ci. A first interlayer dielectric layer 02h covers the second metal layer 02g and the second insulating layer 02f. A second active layer 02i is provided on the first interlayer dielectric layer 02h. The second active layer 02i is overlapped with the second gate g2. A third insulating layer 02j covers the second active layer 02i and the first interlayer dielectric layer 02h. A third metal layer 02k is provided on the third insulating layer 02j. The third metal layer 02k includes a third gate g3 overlapped with the second active layer 02i. A second interlayer dielectric layer 02m covers the third metal layer 02k and the third insulating layer 02j. A fourth metal layer 02n is provided on the second interlayer dielectric layer 02m. The fourth metal layer 02n includes a first source s1, a first drain d1, a second source s2, and a second drain d2. The first source s1 and the first drain d1 are connected to the first active layer 02c. The second source s2 and the second drain d2 are connected to the second active layer 02i.

The inorganic insulating stacked layer dc is defined by stacking the buffer layer 02b, the first insulating layer 02d, the second insulating layer 02f, the first interlayer dielectric layer 02h, the third insulating layer 02j, and the second interlayer dielectric layer 02m. The opening k1 extends through at least one layer of the inorganic insulating stacked layer dc.

That is, the opening k1 may extend through the second interlayer dielectric layer 02m; may extend through the third insulating layer 02j and the second interlayer dielectric layer 02m; may extend through the first interlayer dielectric layer 02h, the third insulating layer 02j and the second interlayer dielectric layer 02m; may extend through the second insulating layer 02f, the first interlayer dielectric layer 02h, the third insulating layer 02j and the second interlayer dielectric layer 02m; may extend through the first insulating layer 02d, the second insulating layer 02f, the first interlayer dielectric layer 02h, the third insulating layer 02j and the second interlayer dielectric layer 02m; and may extend through the buffer layer 02b, the first insulating layer 02d, the second insulating layer 02f, the first interlayer dielectric layer 02h, the third insulating layer 02j and the second interlayer dielectric layer 02m.

The greater the depth of the opening k1, the greater ability to release the stress on the bending portion 10b. Therefore, in order to release the stress on the bending portion 10b to the maximum extent, the opening k1 of the present embodiment extends through the whole layers of the inorganic insulation stacked layer dc.

In an embodiment, the opening k1 covers the entire area of the bending portion 10b, that is, the bending portion 10b is not provided with the inorganic insulating laminate dc, thereby minimizing the stress to which the bending portion 10b is subjected.

In an embodiment, the size of the opening k1 may be set according to actual conditions.

In an embodiment, the display panel 10 further includes a switching portion 02p and a flat layer 02r. The switching portion 02p and the wiring 11 are provided on a same layer and on the organic layer 103. The switching portion 02p is connected to the first drain d1. The flat layer 02r covers the switching portion 02p, the wiring 11, and the organic layer 103.

The light-emitting device fg includes an anode f1, a pixel definition layer f2, a light-emitting layer, and a cathode. The anode f1 is provided on the flat layer 02r, and the anode f1 is connected to the switching portion 02p. The pixel definition layer f2 is provided on the flat layer 02r, and extends to cover the region corresponding to the bending portion 10b.

The groove 12 further extends through the flexible substrate 101. That is, the groove 12 extend through all the film layers of the bending portion 10b of the display panel 10.

In an embodiment, the groove 12 extends through at least a portion of protective layer 33, pixel defining layer f2, planar layer 02r, and organic layer 103. For example, the groove 12 may extend through the flexible substrate 101, and may extend through one of the buffer layer 02b, the first insulating layer 02d, the second insulating layer 02f, the first interlayer dielectric layer 02h, the third insulating layer 02j, and the second interlayer dielectric layer 02m.

In an embodiment, the pixel definition layer f2 may not be provided in the region corresponding to the bending portion 10b.

In an embodiment, the display panel 10 further includes an encapsulating layer 34, and the encapsulating layer 34 is filled in the groove 12. In some embodiments, the groove 12 may be filled by the protective layer 33. That is, the protective layer 33 is formed after bending the bending portion 10b and attaching the display panel 10 with the cover plate 20, to saving the encapsulating layer 34.

### Embodiment 2

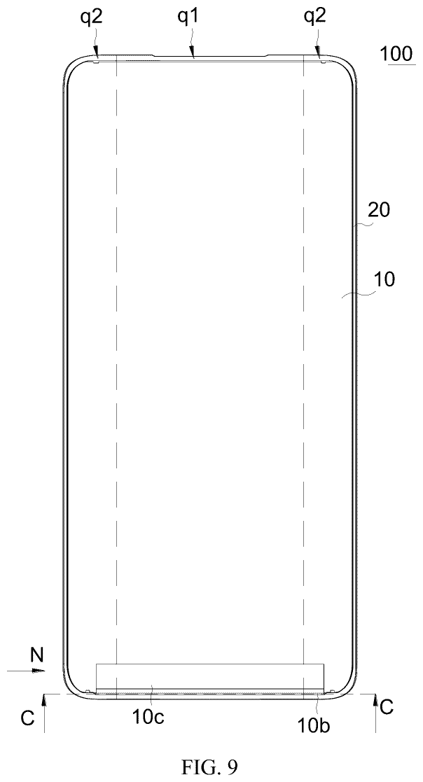

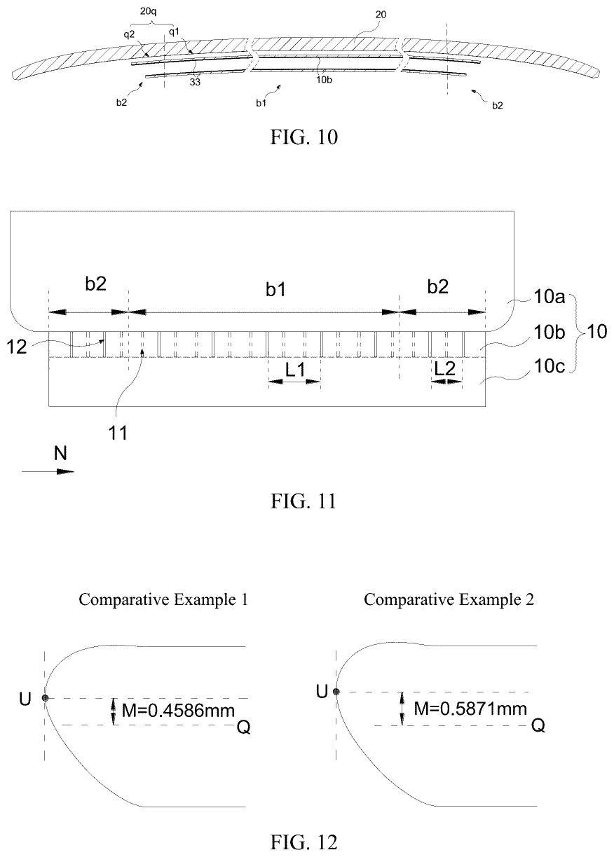

Referring to FIGS. 9 to 11, the display module 100 of the Embodiment 2 of the present application differs from the display module 100 of the Embodiment 1 in that the cover plate 20 has a different configuration, and the bending portion 10b has corresponding partitions as the cover plate 20 is attached to the display panel 10. The following is provided for details.

In the longitudinal axis direction N of the bending portion 10b, the bending portion 10b includes a first region b1 and a second region b2, and the second region b2 is located on the opposite side of the first region b1.

The attaching curved surface 20q includes a first curved surface q1 covering the first region b1 and a second curved surface q2 covering the second region b2. The second curved surface q2 is connected to the opposite side of the first curved surface q1. In the longitudinal axis direction N of the bending portion 10b, the first curved surface q1 has a consistent curvature radius, the second curved surface q2 has a consistent curvature radius, and the curvature radius of the first curved surface q1 is greater than the curvature radius of the second curved surface q2.

With a consistent arc length, the first region b1 has less groove 12 than the second region b2.

The curvature radius of the first curved surface q1 is greater than the curvature radius of the second curved surface q2, as such, the stress applied to the first region b1 of the bending portion 10b is less than the stress applied to the second region b2. Therefore, more grooves 12 are provided in the second region b2 where the stress is greater to release more stress, thereby reducing the risk of breaking the wiring 11.

In an embodiment, the distance L1 between two adjacent grooves 12 in the first region b1 is greater than the distance L2 between two adjacent grooves 12 in the second region b2.

That is, the present embodiment provides different distances to adjust the density of the grooves 12 in the first region b1 and the second region b2. The greater the density, the less the distance between the grooves 12.

In an embodiment, a ratio of the number of the grooves 12 in the first region b1 to the number of the grooves in the second region b2 is negatively correlated with a ratio of the curvature radius of the first curved surface q1 to the curvature radius of the second curved surface q2. For example, in a case that the ratio of the curvature radius of the first curved surface q1 to the curvature radius of the second curved surface q2 is T, and T is greater than 0, the ratio of the number of the grooves 12 in the first region b1 to the number of the grooves 12 in the second region b2 is 1/T.

For example, in a case that the ratio of the curvature radius of the first curved surface q1 to the curvature radius of the second curved surface q2 is 3, the ratio of the number of the grooves 12 in the first region b1 to the number of the grooves 12 in the second region b2 is 1/3.

In addition, in simulation experiment for cellphone, for Comparative Example 1, the curvature radius of the first curved surface q1 is set to be much greater than the curvature radius of the second curved surface q2, and the arc length of the second curved surface q2 is set to be 5 mm; for Comparative Example 2, the curvature radius of the first curved surface q1 is set to be much greater than the curvature radius of the second curved surface q2, and the arc length of the second curved surface q2 is set to be 10 mm.

Here, the curvature radius of the second curved surfaces q2 in two comparative examples are equal, the curvature radius of the first curved surfaces q12 in two comparative examples are equal, and the arc length of the first curved surface q1 and the second curved surface q2 in total in Comparative Example 1 and that in Comparative Example 2 are equal.

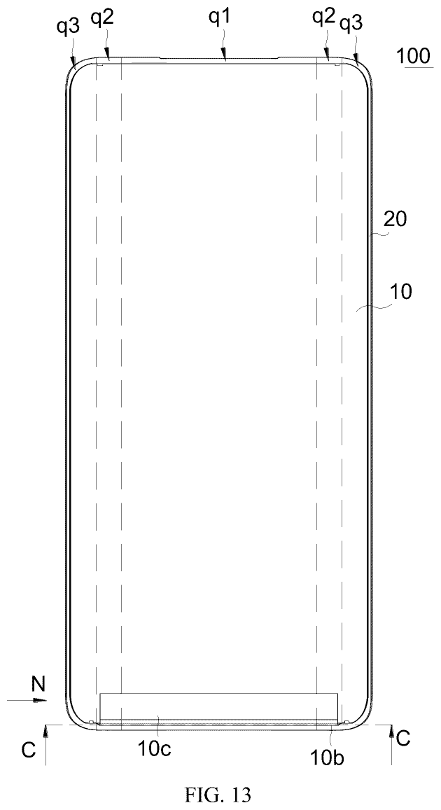

As shown in FIG. 12, with the bending radius of the bending portion 10b (bent toward the back of the display main body 10a) identical, the warping amount M of the bending portion 10b of Comparative Example 1 is 0.4586 mm; and the warping amount M of the bending portion 10b of Comparative Example 2 is 0.5871 mm, which can be seen from FIG. 12.

The warping amount M is the distance between the outer arc convex point U and the central axis Q of the bending portion. The central axis Q is a median line between the upper end and the lower end of the bending portion. The greater the warping amount M, the greater the bending stress to which the bending portion is subjected, and the greater the risk of breakage of the wiring in the bending portion.

As can be seen from FIG. 12, the warping amount M of Comparative Example 2 is increased by about 28% compared with the warping amount M of Comparative Example 1. It can be seen that Comparative Example 2 has a greater bending stress on the bending portion.

In an embodiment, when the display module 100 is used for a cellphone, the arc length of the second curved surface q2 ranges between 3 mm and 10 mm, for example, may be 3 mm, 4 mm, 5 mm, 6 mm, 7 mm, 8 mm, 9 mm, or 10 mm, in the longitudinal axis direction N of the bending portion 10b.

The arc length of the second curved surface q2 is less than or equal to 10 mm, to avoid excessive bending stress on the second region b2 of the bending portion 10b. The arc length of the second curved surface q2 is greater than or equal to 3 mm, to avoid insufficient width at the edge of the region, and reduce the number of the grooves 12.

In an embodiment, the first curved surface q1 and the second curved surface q2 of the cover plate 20 extend beyond the display panel 10.

In an embodiment, the attaching curved surface 20q of the cover plate 20 may have a third curved surface, and the third curved surface is connected to a side of the second curved surface q2 away from the first curved surface q1. The second curved surface q2 covers the bending portion 10b completely, and the third curved surface is located outside the bending portion 10b, that is, the third curved surface does not cover the bending portion 10b.

The curvature radius of the third curved surface decreases in a direction from a side of the third curved surface connected to the second curved surface q2 toward a side of the third curved surface away from the second curved surface q2. The maximum curvature radius of the third curved surface q3 is equal to the curvature radius of the second curved surface q2.

The cover plate 20 includes edge portions having a third curved surface q3 at the sides, to improve the user's grip and smooth narrowing of the bezel.

### Embodiment 3

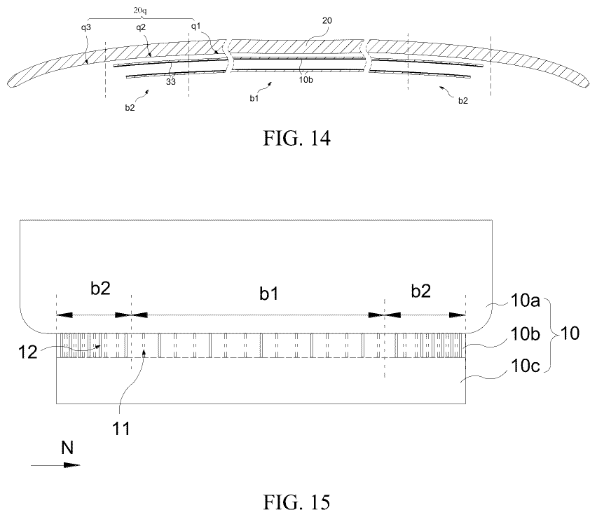

Referring to FIGS. 13 to 15, the display module 100 of the embodiment of the present application differs from the display module 100 of the embodiments described above in that the cover plate 20 has a different configuration, and the bending portion 10b has a corresponding partition as the cover plate 20 is attached to the display panel 10. The following is provided for details.

In the longitudinal axis direction N of the bending portion 10b, the bending portion 10b includes a first region b1 and a second region b2, and the second region b2 is located on the opposite side of the first region b1.

he attaching curved surface 20q includes a first curved surface q1 covering the first region b1 and a second curved surface q2 covering the second region b2. The second curved surface q2 is connected to the opposite side of the first curved surface q1. In the longitudinal axis direction N of the bending portion 10b, the first curved surface q1 has a consistent curvature radius.

The curvature radius of the second curved surface q2 decreases in a direction from a side of the second curved surface q2 connected to the first curved surface q1 toward a side of the second curved surface q2 away from the first curved surface q1.

With a consistent arc length, the first region b1 has less groove 12 than the second region b2.

The curvature radius of the first curved surface q1 is equal to the maximum curvature radius of the second curved surface q2, as such, the stress applied to the first region b1 of the bending portion 10b is less than the stress applied to the second region b2. Therefore, more grooves 12 are provided in the second region b2 where the stress is greater to release more stress, thereby reducing the risk of breaking the wiring 11.

In an embodiment, the distance between two adjacent grooves 12 in the first region b1 is greater than the distance between two adjacent grooves 12 in the second region b2.

That is, the present embodiment provides different distances to adjust the density of the grooves 12 in the first region b1 and the second region b2. The greater the density, the less the distance between the grooves 12.

In an embodiment, the density of the grooves 12 increases in a direction from a side of the second region b2 connected to the first region b1 toward a side of the second region b2 away from the first region b1.

The less the curvature radius of the attaching curved surface 20q is, the greater bending stress on the bending portion 10b is. Therefore, the density of the grooves 12 increases in the second region b2, to better release the bending stress on the second region b2 and to reduce the risk of the breakage of the wiring 11.

In an embodiment, the first curved surface q1 and the second curved surface q2 of the cover plate 20 extend beyond the display panel 10.

In an embodiment, the attaching curved surface 20q of the cover plate 20 may have a third curved surface, and the third curved surface is connected to a side of the second curved surface q2 away from the first curved surface q1.

The curvature radius of the third curved surface q3 decreases in a direction from a side of the third curved surface q3 connected to the second curved surface q2 toward a side of the third curved surface q3 away from the second curved surface q2. The maximum curvature radius of the third curved surface q3 is equal to the curvature radius of the second curved surface q2.

The cover plate 20 includes edge portions having a third curved surface q3 at the sides, to improve the user's grip and smooth narrowing of the bezel.

### Embodiment 4

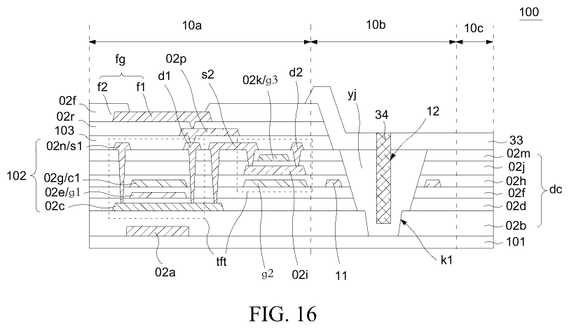

Referring to FIG. 16, the display module 100 of the embodiment of the present application differs from the display module 100 of the embodiments described above in that the cover plate 20 has a different configuration. The following is provided for details.

The display panel 10 includes a flexible substrate 101, a thin film transistor structure layer 102, and an organic layer 103.

The flexible substrate 101 is provided corresponding to the display main body 10a, the bending portion 10b, and the binding portion 10c.

The thin film transistor structure layer 102 includes a thin film transistor tft located in the display main body 10a, and an inorganic insulating stack dc. The inorganic insulating stacked layer dc is provided corresponding to the display main body 10a, the bending portion 10b, and the binding portion 10c. The inorganic insulating stacked layer dc is provided with a plurality of openings k1. The openings k1 is provided corresponding to the bending portion 10b. The plurality of openings k1 are arranged along the longitudinal axis direction N of the bending portion 10b. The openings k1 extend in the bending direction W of the bending portion 10b. At least one of the source electrode, drain electrode and gate electrode of the thin film transistor tft is provided in a same layer as the wiring 11.

The organic layer 103 is provided corresponding to the display main body 10a.

Each of the openings k1 is filled with the organic material yj, and the groove k1 is defined in the organic material yj. The depth of the opening k1 is less than the thickness of the organic material yj, and the width of the groove 12 is less than the width of the organic material yj.

The wiring 11 is provided in the same layer as at least one of the source electrode, the drain electrode, or the gate electrode of the thin film transistor tft. Compared with the above-described embodiment, the thickness of the bending portion 10b is reduced, thereby reducing the bending stress on the bending portion 10b. Further, the organic layer 103, the flat layer 02r, and the pixel definition layer f2 are not provided corresponding to the bending portion 10b, to further reduce the thickness of the bending portion 10b.

In an embodiment, the organic material yj may be formed by a same process as the organic layer 103, that is, the organic material yj has same material with the organic layer 103.

In addition, the depth of the groove 12 is less than the total of the thickness of the organic material yj and the thickness of the protective layer 33, as such, the groove 12 cannot penetrate through the organic material yj. Thus, the inorganic insulating stacked layer dc on both sides of the opening k1 are connected by the organic material yj, thereby improving the overall stability of the bending portion 10b and the waterproof oxygen performance.

In an embodiment, at least one of the light-shielding layer 02a, the first metal layer 02e, the second metal layer 02g, the third metal layer 02k, and the fourth metal layer 02n is provided in a same layer as the wiring 11.

In an embodiment, the groove 12 extends through all film layers of the bending portion 10b to improve the bending resistance of the bending portion 10b.

In an embodiment, the groove 12 may be filled with the protective layer 33. That is, the protective layer 33 is formed after the bending portion 10b is bent and the display panel 10 is attached to the cover plate 20, to save the encapsulating layer 34.

### Embodiment 5

Accordingly, the embodiment of the present application further provides a display terminal including the display module 100 according to any one of the above-described embodiments.

In an embodiment, the display terminal may be a television, a cellphone, a tablet computer, a laptop computer, a desktop computer, an intelligent wearable display device (such as a watch, a bracelet, or the like), a VR device, or an AR device.

The display module of the display terminal of the present embodiment is similar or identical in structure to the display module 100 of any one of the above-described embodiments.

A display module according to an embodiment of the present application includes a display panel and a cover plate. The display panel includes a display main body, a bending portion, and a binding portion connected sequentially, and the binding portion is provided on a back of the display main body through the bending portion. The cover plate has an attaching curved surface facing the display panel, a portion of the attaching curved surface is adhered to a display side of the display panel through transparent glue, and the attaching curved surface covers the display main body and the bending portion completely. The bending portion includes a wiring, and at least one groove is defined in the bending portion. The groove extends along a bending direction of the bending portion and is positioned outside the wiring.

The display module according to the embodiment of the present application is provided with a groove on the bending portion to release the bending stress on the bending portion, thereby reducing a risk of breakage of the wiring in the bending portion.

The embodiments of the present application are described in detail with reference to a display module and a display terminal. The principles and embodiments of the present application are described herein using specific examples. The description of the above embodiments is merely provided to help understand the method and the core idea of the present application. The variations will occur to those skilled in the art in the embodiments and the scope of application in accordance with the teachings of the present application. In view of the foregoing, the present description should not be construed as limiting the application.

1. A display module, comprising:
a display panel, wherein the display panel includes a display main body, a bending portion, and a binding portion sequentially connected to each other, and the binding portion is provided on a back of the display main body through the bending portion; and
a cover plate, wherein the cover plate has an attaching curved surface facing the display panel, a portion of the attaching curved surface is attached to a display side of the display panel by a transparent glue, and the attaching curved surface fully covers the display main body and the bending portion;
wherein the bending portion includes a wiring and at least one groove, and the groove extends along a bending direction of the bending portion and is disposed outside the wiring.

2. The display module of claim 1, wherein in a longitudinal axis direction of the bending portion, the attaching curved surface has a consistent curvature radius, and a plurality of the grooves are uniformly disposed.

3. The display module of claim 1, wherein in a longitudinal axis direction of the bending portion, the bending portion includes a first region and a second region, and the second region is disposed on an opposite side of the first region;
wherein the attaching curved surface comprises a first curved surface covering the first region and a second curved surface covering the second region, the second curved surface is connected to the first curved surface at opposite sides, and in the longitudinal axis direction of the bending portion, a curvature radius of the first curved surface is consistent, a curvature radius of the second curved surface is consistent, and the curvature radius of the first curved surface is greater than the curvature radius of the second curved surface;
wherein a number of the grooves in the first region is smaller than a number of the grooves in the second region at same arc length.

4. The display module of claim 3, wherein a distance between two adjacent grooves of the first region is greater than a distance between two adjacent grooves of the second region.

5. The display module of claim 1, wherein in a longitudinal axis direction of the bending portion, the bending portion includes a first region and a second region, and the second region is disposed on an opposite side of the first region;
wherein the attaching curved surface includes a first curved surface covering the first region and a second curved surface covering the second region, the second curved surface is connected to the first curved surface at opposite sides, and in the longitudinal axis direction of the bending portion, a curvature radius of the first curved surface is consistent, and a curvature radius of the second curved surface decreases in a direction from a side of the second curved surface connected to the first curved surface toward a side of the second curved surface away from the first curved surface;
wherein a number of the grooves in the first region is smaller than a number of the grooves in the second region at same arc length.

6. The display module of claim 5, wherein a density of the grooves in the second region increases in a direction from a side of the second region connected to the first region toward a side of the second region away from the first region.

7. The display module of claim 1, wherein the display panel comprises:
a flexible substrate provided corresponding to the display body, the bending portion, and the binding portion;
a thin film transistor structure layer, wherein the thin film transistor structure layer includes a thin film transistor and an inorganic insulating stacked layer, the thin film transistor is provided corresponding to the display main body, the inorganic insulating stacked layer is disposed at least corresponding to the display main body and the binding portion, the inorganic insulating stacked layer being provided with an opening, and the opening is disposed corresponding to the bending portion; and
an organic layer disposed on the thin film transistor structure layer, wherein the organic layer is extended from the display body to cover the bending portion and filled in the opening, and the wiring is disposed on the organic layer;
wherein in the bending portion, the organic layer is provided with the groove, and the groove is extended through at least a portion of the organic layer.

8. The display module of claim 7, wherein the groove is extended through all film layers of the bending portion.

9. The display module of claim 7, wherein the thin film transistor structure layer comprises a light-shielding layer, a buffer layer, a first active layer, a first insulating layer, a first metal layer, a second insulating layer, a second metal layer, a first interlayer dielectric layer, a second active layer, a third insulating layer, a third metal layer, a second interlayer dielectric layer, and a fourth metal layer;
wherein the light-shielding layer is disposed on the flexible substrate; the buffer layer is disposed on the light-shielding layer and covers the flexible substrate; the first active layer is disposed on the buffer layer; the first insulating layer covers the first active layer and the buffer layer; the first metal layer is disposed on the first insulating layer; the first metal layer includes a first gate electrode overlapped with the first active layer; the second insulating layer covers the first metal layer and the first insulating layer; the second metal layer is disposed on the second insulating layer; the second metal layer includes an electrode plate and a second gate electrode; the electrode plate is overlapped with the first gate electrode to define a capacitance; the second gate electrode is disposed on a side of the electrode plate; the first interlayer dielectric layer covers the second metal layer and the second insulating layer; the second active layer is disposed on the first interlayer dielectric layer; the second active layer is overlapped with the second gate electrode; the third insulating layer covers the second active layer and the first interlayer dielectric layer; the third metal layer is disposed on the third insulating layer; the third metal layer comprises a third gate electrode overlapped with the second active layer; the second interlayer dielectric layer covers the third metal layer and the third insulating layer; the fourth metal layer is disposed on the second interlayer dielectric layer; the fourth metal layer comprises a first source electrode, a first drain electrode, a second source electrode and a second drain electrode; the first source electrode and the first drain electrode are connected to the first active layer; and the second source electrode and the second drain electrode are connected to the second active layer;
wherein the buffer layer, the first insulating layer, the second insulating layer, the first interlayer dielectric layer, the third insulating layer, and the second interlayer dielectric layer are stacked to define the inorganic insulating stacked layer, and the opening is extended through at least one layer of the inorganic insulating stacked layer.

10. The display module of claim 7, wherein the display panel further comprises a protective layer covering the bending portion, the protective layer is extended to cover a portion of the display main body and a portion of the binding portion, and the groove is extended through the protective layer;
wherein the display panel includes an encapsulating glue filled in the groove.

11. The display module of claim 1, wherein the display panel comprises:
a flexible substrate provided corresponding to the display body, the bending portion, and the binding portion; and
a thin film transistor structure layer, wherein the thin film transistor structure layer includes a thin film transistor and an inorganic insulating stacked layer; the thin film transistor is provided corresponding to the display main body; the inorganic insulating stacked layer is disposed corresponding to the display main body, the bending portion, and the binding portion; the inorganic insulating stacked layer is provided with a plurality of openings corresponding to the bending portion; the plurality of opening is arranged in a longitudinal axis direction of the bending portion, and is extended in a bending direction of the bending portion; and at least one of a source electrode, a drain electrode, and a gate electrode of the thin film transistor is disposed in a same layer with the wiring;
wherein each of the plurality of openings is filled with an organic material, the groove is defined on the organic material, and a depth of the groove is less than a thickness of the organic material, or the groove penetrates through all film layers of the bending portion.

12. A display terminal, comprising a display module, wherein the display module comprises:
a display panel, wherein the display panel includes a display main body, a bending portion, and a binding portion sequentially connected to each other, and the binding portion is provided on a back of the display main body through the bending portion; and
a cover plate, wherein the cover plate has an attaching curved surface facing the display panel, a portion of the attaching curved surface is attached to a display side of the display panel by a transparent glue, and the attaching curved surface fully covers the display main body and the bending portion;
wherein the bending portion includes a wiring and at least one groove, and the groove extends along a bending direction of the bending portion and is disposed outside the wiring.

13. The display terminal of claim 12, wherein in a longitudinal axis direction of the bending portion, the attaching curved surface has a consistent curvature radius, and a plurality of the grooves are uniformly disposed.

14. The display terminal according to claim 12, wherein in a longitudinal axis direction of the bending portion, the bending portion includes a first region and a second region, and the second region is disposed on an opposite side of the first region;
wherein the attaching curved surface comprises a first curved surface covering the first region and a second curved surface covering the second region, the second curved surface is connected to the first curved surface at opposite sides, and in the longitudinal axis direction of the bending portion, a curvature radius of the first curved surface is consistent, a curvature radius of the second curved surface is consistent, and the curvature radius of the first curved surface is greater than the curvature radius of the second curved surface;
wherein a number of the grooves in the first region is smaller than a number of the grooves in the second region at same arc length.

15. The display terminal of claim 14, wherein a distance between two adjacent grooves of the first region is greater than a distance between two adjacent grooves of the second region.

16. The display terminal of claim 12, wherein in a longitudinal axis direction of the bending portion, the bending portion includes a first region and a second region, and the second region is disposed on an opposite side of the first region;
wherein the attaching curved surface includes a first curved surface covering the first region and a second curved surface covering the second region, the second curved surface is connected to the first curved surface at opposite sides, and in the longitudinal axis direction of the bending portion, a curvature radius of the first curved surface is consistent, and a curvature radius of the second curved surface decreases in a direction from a side of the second curved surface connected to the first curved surface toward a side of the second curved surface away from the first curved surface;
wherein a number of the grooves in the first region is smaller than a number of the grooves in the second region at same arc length.

17. The display terminal of claim 16, wherein a density of the grooves in the second region increases in a direction from a side of the second region connected to the first region toward a side of the second region away from the first region.

18. The display terminal of claim 12, wherein the display panel comprises:
a flexible substrate provided corresponding to the display body, the bending portion, and the binding portion;
a thin film transistor structure layer, wherein the thin film transistor structure layer includes a thin film transistor and an inorganic insulating stacked layer, the thin film transistor is provided corresponding to the display main body, the inorganic insulating stacked layer is disposed at least corresponding to the display main body and the binding portion, the inorganic insulating stacked layer being provided with an opening, and the opening is disposed corresponding to the bending portion; and
an organic layer disposed on the thin film transistor structure layer, wherein the organic layer is extended from the display body to cover the bending portion and filled in the opening, and the wiring is disposed on the organic layer;
wherein in the bending portion, the organic layer is provided with the groove, and the groove is extended through at least a portion of the organic layer.

19. The display terminal of claim 18, wherein the groove is extended through all film layers of the bending portion.

20. The display terminal of claim 18, wherein the thin film transistor structure layer comprises a light-shielding layer, a buffer layer, a first active layer, a first insulating layer, a first metal layer, a second insulating layer, a second metal layer, a first interlayer dielectric layer, a second active layer, a third insulating layer, a third metal layer, a second interlayer dielectric layer, and a fourth metal layer;
wherein the light-shielding layer is disposed on the flexible substrate; the buffer layer is disposed on the light-shielding layer and covers the flexible substrate; the first active layer is disposed on the buffer layer; the first insulating layer covers the first active layer and the buffer layer; the first metal layer is disposed on the first insulating layer; the first metal layer includes a first gate electrode overlapped with the first active layer; the second insulating layer covers the first metal layer and the first insulating layer; the second metal layer is disposed on the second insulating layer; the second metal layer includes an electrode plate and a second gate electrode; the electrode plate is overlapped with the first gate electrode to define a capacitance; the second gate electrode is disposed on a side of the electrode plate; the first interlayer dielectric layer covers the second metal layer and the second insulating layer; the second active layer is disposed on the first interlayer dielectric layer; the second active layer is overlapped with the second gate electrode; the third insulating layer covers the second active layer and the first interlayer dielectric layer; the third metal layer is disposed on the third insulating layer; the third metal layer comprises a third gate electrode overlapped with the second active layer; the second interlayer dielectric layer covers the third metal layer and the third insulating layer; the fourth metal layer is disposed on the second interlayer dielectric layer; the fourth metal layer comprises a first source electrode, a first drain electrode, a second source electrode and a second drain electrode; the first source electrode and the first drain electrode are connected to the first active layer; and the second source electrode and the second drain electrode are connected to the second active layer;
wherein the buffer layer, the first insulating layer, the second insulating layer, the first interlayer dielectric layer, the third insulating layer, and the second interlayer dielectric layer are stacked to define the inorganic insulating stacked layer, and the opening is extended through at least one layer of the inorganic insulating stacked layer.
